(19) United States
(12) Patent Application Publication
(10) Pub. No.: US 2020/0044612 A1
(43) Pub. Date: Feb. 6, 2020

(54) TRANSMITTER DYNAMIC RF POWER CONTROL VIA VSWR DETECTION FOR WIRELESS RADIOS

(71) Applicant: ADVANCED MICRO DEVICES, INC., Santa Clara, CA (US)

(72) Inventors: Benny Joseph BOLOGNA, Austin, TX (US); Todd W. STEIGERWALD, Austin, TX (US); Efstratios SKAFIDAS, Melbourne (AU)

(21) Appl. No.: 16/050,984

(22) Filed: Jul. 31, 2018

(51) Int. Cl. H03F 1/02; H03F 3/24

(52) U.S. Cl. CPC H03F 1/0233; H03F 3/245; H03F 3/193; H03F 2200/198; H03F 2200/471; H03F 2200/132

(57) ABSTRACT

An electronic device includes a power amplifier that sets the power of a transmit signal that is transmitted via an antenna of the device, and further includes a VSWR detector to identify the VSWR at a signal path between the antenna and the power amplifier. As a person (e.g., a user) moves in close proximity to the antenna, the amount of reflected energy along the signal path increases, thereby increasing the VSWR. A power controller of the electronic device sets a gain of the power amplifier based on the VSWR to ensure that the SAR exposure to the person is maintained below a specified threshold.

### BACKGROUND

### Description of the Related Art

Hand-held and other electronic devices that transmit radio frequency (RF) signals are known to emit radiation that can be absorbed by persons in close proximity to the electronic device. Exposure to such radiation is sometimes referred to as Specific Absorption Rate (SAR) exposure. To reduce potential health risks from SAR exposure, the Federal Communications Commission mandates requirements for the level of SAR exposure that can be generated by specified devices, such as cell phones. Because the amount of radiation generated by an electronic device is proportional to the amount of power used to generate the corresponding transmitted RF signal (the transmit power), the FCC requirements can be met by placing a limit on the maximum transmit power for the device. However, limiting the transmit power of the device in this way can undesirably reduce the transmit range and reliability for the device. Some devices employ a dynamic power control scheme, wherein dedicated proximity sensors detect the presence of a person near the device, and in response temporarily reduce the transmit power. However, conventional dynamic power control schemes are difficult to implement, requiring additional hardware, such as proximity sensors, and/or complex software development.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of an electronic device that controls transmit RF power based on monitoring a voltage standing wave ratio (VSWR) on a signal path between a power amplifier and an antenna in accordance with some embodiments.

FIG. 2 is a circuit diagram illustrating a power control feedback loop of the electronic device of FIG. 1 in accordance with some embodiments.

FIG. 3 is a diagram illustrating an example of transmit power control based on user proximity to the electronic device of FIG. 1 in accordance with some embodiments.

FIG. 4 is a flow diagram of a method of controlling transmit power at an electronic device based on monitoring VSWR in accordance with some embodiments.

### DETAILED DESCRIPTION

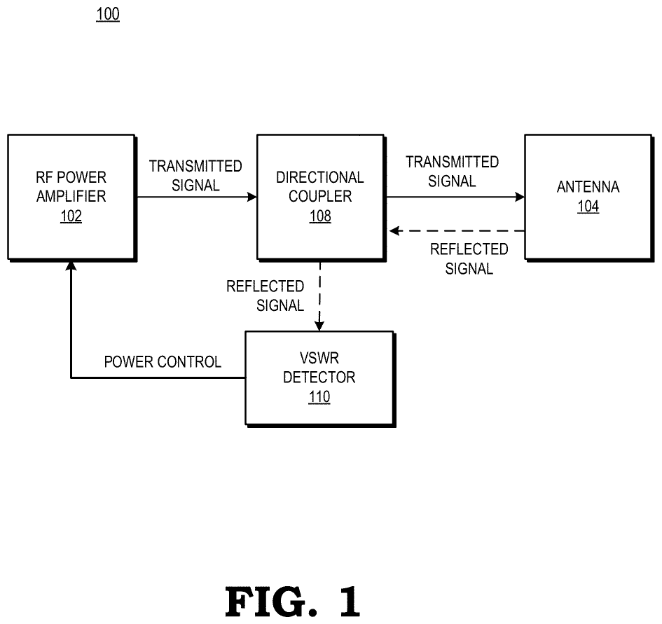

FIGS. 1-4 illustrate techniques for controlling transmit RF power at an electronic device based on monitoring a voltage standing wave ratio (VSWR). The electronic device includes a power amplifier that sets the power of a transmit signal that is transmitted via an antenna of the device, and further includes a VSWR detector to identify the VSWR at a signal path between the antenna and the power amplifier. As a person (e.g., a user) moves in close proximity to the antenna, the amount of reflected energy along the signal path increases, thereby increasing the VSWR. A power controller of the electronic device sets a gain of the power amplifier based on the VSWR to ensure that the SAR exposure to the person is maintained below a specified threshold. By detecting proximity using VSWR, SAR exposure is maintained below the threshold without the use of additional proximity sensors or placing a fixed limit on transmit power, thereby simplifying device design and implementation while maintaining a satisfactory user experience.

FIG. 1 illustrates a block diagram of an electronic device 100 that controls transmit power based on monitoring VSWR in accordance with some embodiments. The electronic device 100 is any device that transmits signals and whose proximity to a user or other person varies during normal use. Thus, in various embodiments the electronic device 100 is a handheld device such as a cell phone or a tablet, a laptop or desktop computer, a server, a game console, and the like. In some embodiments, the electronic device 100 includes modules and circuits not specifically illustrated at FIG. 1, such as one or more processing units (e.g. CPUs and GPUs) configured to execute instructions to perform operations on behalf of the electronic device 100. As part of these operations, the processing units generate data for transmission via a wireless transceiver of the electronic device 100. The wireless transceiver is generally configured to transmit data according to one or more corresponding wireless communication standards, such as one or more Bluetooth, wireless local area network (WLAN), and wireless wide area network (WWAN) standards.

FIG. 1 illustrates portions of the above-referenced wireless transceiver, including a power amplifier 102 and an antenna 104. The power amplifier 102 is generally configured to receive an input signal representing data to be transmitted and to amplify a magnitude of the input signal based on the gain of the power amplifier 102. In the embodiment of FIG. 1, the gain of the power amplifier 102 is an adjustable value that is controlled by a signal designated POWER CONTROL. As described further herein, the electronic device 100 is configured to adjust the POWER CONTROL signal, and therefore the gain of the power amplifier 102 to maintain SAR exposure associated with the electronic device 100 within acceptable limits.

The antenna 104 is generally configured to receive the output signal (that is, the amplified input signal) of the power amplifier 102 via a signal path and to wirelessly transmit the received signal. In some embodiments, the signal path is a transmission line, metal wire or other conductor that transfers signals from the power amplifier 102 to the antenna 104. In other embodiments, the signal path can include one or more modules not specifically illustrated at FIG. 1, such as one or more filters, couplers, diodes, and the like to support good signal fidelity and other specified requirements for the transferred signal.

In some scenarios, a user or other person in proximity to the electronic device 100 is exposed to near field RF radiation as a result of the antenna 104 transmitting RF signals. To ensure that SAR exposure resulting from the RF radiation is maintained below specified limits (e.g., the limits set by the FCC), the electronic device 100 employs a directional coupler 108 to provide a reflected signal from the antenna 104 to a VSWR detector 110, which detects increased reflection from the antenna caused by the close near field proximity of a person to the antenna 104 and adjusts the POWER CONTROL signal based on the detected proximity. For example, in response to detecting that a person is within a threshold distance to the antenna 104 as indicated by an increase in the magnitude of the reflected signal, the VSWR detector 110 adjusts the POWER CONTROL signal to reduce the gain of the power amplifier 102. This in turn reduces the transmit power for the signal transmitted by the antenna 104, thereby reducing the level of RF radiation and therefore the SAR exposure level. In response to the VSWR detector 110 identifying that a person is no longer within the threshold distance, the VSWR detector 110 adjusts the POWER CONTROL signal to increase the gain of the power amplifier 102, thereby increasing the transmit power for the signal transmitted by the antenna 104. Thus, the VSWR detector 110 dynamically adjusts the transmit power of the electronic device 100 based on a person's proximity to the antenna 104, thereby maintaining SAR exposure below the specified limit while supporting sufficient transmit power for a satisfactory user experience.

To detect the person's proximity to the antenna 104, the VSWR detector 110 identifies the VSWR along the signal path. Close proximity to the antenna refers to the near field region of the antenna that is susceptible to impedance changes, thus increasing the magnitude of reflected signal in the intended frequency band when loaded by a human body. In some embodiments, the VSWR detector 110 identifies the VSWR by monitoring a power level, referred to as reflected power, of a reflected signal transmitted along the signal path, and calculates the VSWR according to the following formula:

$$VSWR = \frac{1 + \vert Γ \vert}{1 - \vert Γ \vert}$$

where Γ is the reflection coefficient calculated according to the following formula:

$$Γ = \frac{{V}_{r}}{{V}_{t}}$$

where Vₜ is the voltage magnitude of the signal provided by the power amplifier 102 along the signal path and Vᵣ is the voltage magnitude of the reflected signal along the signal path.

In operation, in the absence of a person in relatively close proximity to the antenna 104, Vᵣ is relatively low, and therefore the VSWR value is also relatively low. As the person moves in close proximity to the antenna 104, Vᵣ increases as signals are reflected by the person to the antenna 104 and the signal path. The increase in Vᵣ results in an increase in the VSWR value. In response to the increase in the VSWR value, the VSWR detector adjusts the POWER CONTROL signal to reduce the gain of the power amplifier, thus reducing the SAR exposure level when the person moves in close proximity to the antenna 104.

In some embodiments, the VSWR detector 110 is configured to adjust the POWER CONTROL signal based on the relationship of the VSWR value to one or more threshold values. Thus, for example, in some embodiments the VSWR detector 110 compares the VSWR level to a threshold value corresponding to a specified proximity of a person to the antenna 104. In response to the VSWR value exceeding the threshold, the VSWR detector 110 adjusts the gain of the power amplifier 102, using the POWER CONTROL signal, by a specified amount. In other embodiments, the VSWR detector 110 adjusts the POWER CONTROL signal to maintain a specified relationship, such as a specified linear relationship or other specified mathematical relationship, between the VSWR level and the gain of the power amplifier 102. In some embodiments, to allow the electronic device 100 to be used in a variety of environments and applications, the one or more thresholds or the mathematical relationship that govern modification of the gain of the power amplifier 102 are, or are based on, programmable values that are set by a programmer of the electronic device 100.

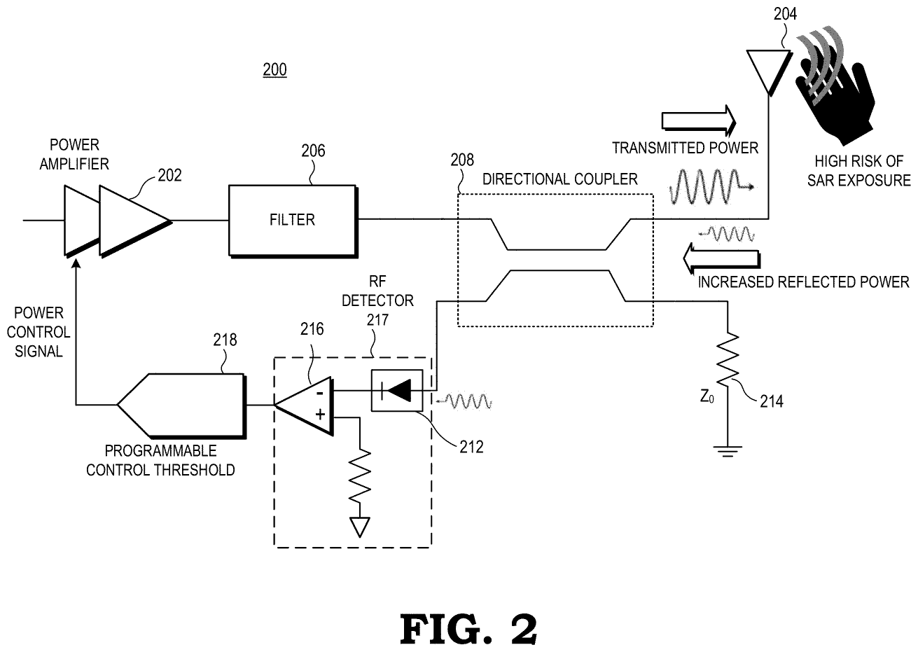

FIG. 2 illustrates a circuit diagram of a circuit 200 including a feedback control loop that adjusts a gain of a power amplifier based on a measured VSWR in accordance with some embodiments. In some embodiments, the circuit 200 is employed at the electronic device 100 and forms at least a portion of the VSWR detector 110. The circuit 200 includes a power amplifier 202 (corresponding in some embodiments to the power amplifier 102 of FIG. 1), an antenna 204 (corresponding in some embodiments to the antenna 104 of FIG. 1), a filter 206, a directional coupler 208, a resistor 214, an RF detector 217 including a diode 212 and a driver 216, and a control module 218. The power amplifier 202 includes an input to receive an input signal and an output. The filter 206 includes an input connected to the output of the power amplifier 202 and an output.

The directional coupler 208 includes a terminal connected to the output of the filter 206, a terminal connected to the antenna 204, a terminal connected to a terminal of the RF detector 217, and a terminal connected to a terminal of the resistor 214. The resistor 214 includes another terminal connected to a ground reference voltage. The control module 218 includes an input connected to the output of the RF detector 217 and an output to provide the POWER CONTROL signal to the power amplifier 202.

In at least one embodiment, the directional coupler 208 is generally arranged so that the input port is connected to the output of the filter 206, transmitted port is coupled to the antenna 204, the coupled port is connected to the resistor 214, and the isolated port is connected to the input of RF detector 217. The directional coupler 208 is thus connected, and the resistor 214 sized, so that in the absence of a presence near the antenna 204, and assuming the power amplifier 202 is providing the output signal at a nominal power level, the amount of reflected power at the isolated port (and therefore at the input of the RF detector 217) is relatively low. When a person moves to within a threshold proximity of the antenna 204, the effective impedance of the antenna 204 is altered, so that the amount of reflected power at the negative input of the detector circuit increases.

The control module 218 is generally configured to measure the signal provided by the RF detector 217 and based on the measured signal generate VSWR values for the signal provided to the antenna 204. The control module 218 is further configured to compare the measured VSWR value to a programmable control threshold and, in response to determining that the VSWR value exceeds the threshold, sets the POWER CONTROL to reduce the gain of the power amplifier 202, reducing the power of the output signal provided to the antenna 204, thereby reducing SAR radiation levels to within a specified tolerance. The control module 218 continues to measure the reflected power from the antenna 204 and, in response to the VSWR value falling below the threshold (indicating that the person is no longer within the threshold proximity of the antenna 204) sets the POWER control signal to return the power of the output signal to the nominal power level.

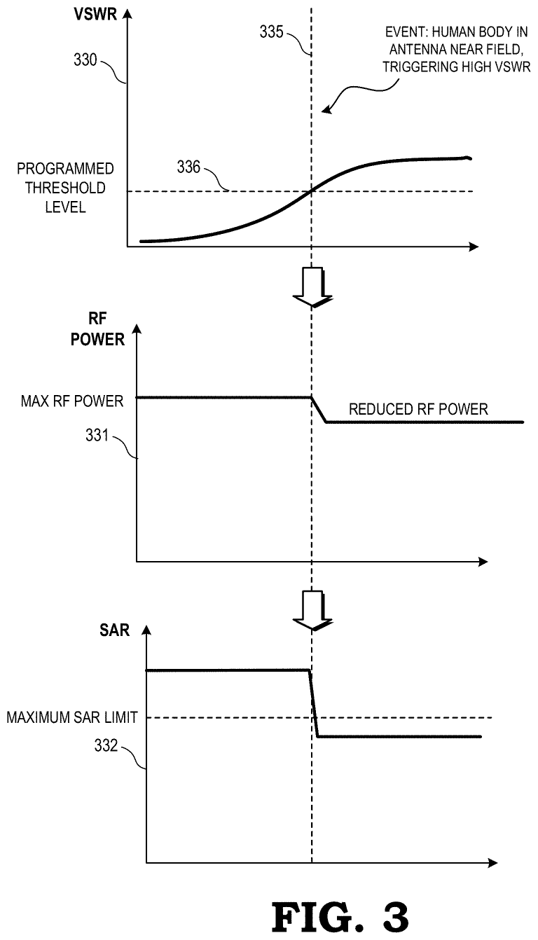

FIG. 3 illustrates a diagrams 330, 331, and 332 that together illustrate an example of transmit power control based on user proximity to the electronic device 100 of FIG. 1 in accordance with some embodiments. The x axes of each of the diagrams 330, 331, and 332 each represent time, while the y-axis of the diagram 330 represents the VSWR measured by the VSWR detector 110, the y-axis of the diagram 331 represents the RF power of the output signal of the power amplifier 102, and the y-axis of the diagram 332 represents the level of SAR radiation emitted by the antenna 104.

In the depicted example, prior to a time 335, a human body is not within a threshold proximity to the antenna 104. Accordingly, the VSWR detected by the VSWR detector 110 is below a threshold level 336. The VSWR detector 110 thereby sets the POWER CONTROL signal to set the power output of the power amplifier 102 to a maximum level. Therefore, prior to the time 335 the level of SAR radiation is above a threshold set by the FCC, as illustrated by diagram 332. At time 335, a human body moves within a threshold proximity to the antenna 104, thereby increasing the VSWR above the threshold level 3336. In response, the VSWR detector 110 adjusts the POWER CONTROL signal to reduce the power of the output signal of the power amplifier 102, as illustrated by diagram 331. The adjustment in the POWER CONTROL signal causes the level of SAR radiation to fall below the FCC threshold, as illustrated by diagram 332.

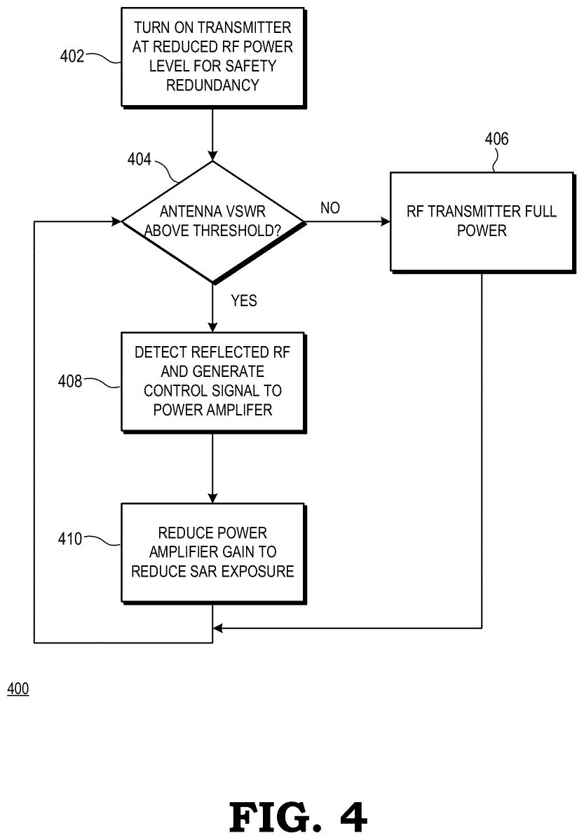

FIG. 4 illustrates a flow diagram of a method 400 of controlling transmit power at an electronic device based on monitoring VSWR in accordance with some embodiments. For purposes of description, the method 400 is described with respect to an example implementation at the electronic device 100 of FIG. 1. At block 402, the electronic device 100 is turned on or reset. At this point, the proximity of a person to the antenna 104 is unknown. Accordingly, to ensure that SAR exposure is maintained within specified limits, the electronic device 100 initializes the power amplifier 102 to have a relatively low gain.

At block 404, the VSWR detector 110 measures the VSWR along the signal path and compares the VSWR to a threshold value. If the VSWR is below the threshold value, the method flow moves to block 406 and the VSWR detector 110 sets the POWER CONTROL signal to increase the gain of the power amplifier 102 to a full, nominal level. The method flow returns to block 404 and the VSWR detector 110 continues to monitor the VSWR along the signal path.

At block 404, in response to the VSWR detector 110 determining that the VSWR is above the threshold value, the method flow moves to block 408 and the VSWR detector detects the amount of reflected power along the signal path. Based on the reflected power, the VSWR detector sets the POWER CONTROL signal to reduce the gain of the power amplifier 102. At block 410, based on the adjusted POWER CONTROL signal, the gain of the power amplifier 102 is reduced, thereby reducing SAR exposure to any person in proximity to the antenna 104.

A computer readable storage medium may include any non-transitory storage medium, or combination of non-transitory storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

In some embodiments, certain aspects of the techniques described above may implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. A method comprising:
identifying a voltage standing-wave ratio (VSWR) for a voltage provided by a power amplifier to an antenna; and
adjusting the power amplifier in response to the VSWR indicating a human body presence in near field proximity to the antenna.

2. The method of claim 1, wherein identifying the VSWR comprises:
detecting a reflected signal on a signal path between the power amplifier and the antenna; and
identifying the VSWR based on the reflected signal.

3. The method of claim 2, wherein identifying VSWR comprises:
identifying a reflection coefficient based on the reflected signal and a signal transmitted to the antenna along the signal path; and
identifying the VSWR based on the reflection coefficient.

4. The method of claim 3, wherein detecting the reflected signal comprises:
detecting the reflected signal at a directional coupler in the signal path, and using an RF detector to rectify the reflected signal.

5. The method of claim 1, wherein adjusting the power amplifier comprises:
reducing a power output of the power amplifier in response to the VSWR exceeding a threshold.

6. The method of claim 5, wherein the threshold is a programmable value.

7. The method of claim 1, wherein adjusting the power amplifier comprises:
reducing a power output of the power amplifier by an adjustment amount, the adjustment amount based on the VSWR.

8. A method comprising:
identifying a proximity of a human body presence to an antenna of a device based on a voltage standing-wave ratio (VSWR) for a voltage provided by a power amplifier to the antenna; and
adjusting the power amplifier based on the identified proximity.

9. The method of claim 8, wherein adjusting the power amplifier comprises:
adjusting a power supplied to the power amplifier by a first amount in response to identifying the proximity is within a first threshold; and
adjusting the power supplied the power amplifier by a second amount in response to identifying the proximity is within a second threshold.

10. The method of claim 8, wherein adjusting the power amplifier comprises:
adjusting a power supplied to the power amplifier to a pre-calibrated level in response to identifying the proximity is within a threshold.

11. The method of claim 10, wherein the threshold is a programmable value.

12. The method of claim 8, further comprising:
detecting a reflected signal on a signal path between the power amplifier and the antenna; and
identifying the VSWR based on the reflected signal.

13. The method of claim 12, wherein identifying VSWR comprises:
identifying a reflection coefficient based on the reflected signal and a signal transmitted to the antenna along the signal path; and
identifying the VSWR based on the reflection coefficient.

14. A device, comprising:
a power amplifier;
an antenna coupled to the power amplifier via a signal path or transmission line;
a voltage standing-wave ratio (VSWR) detector configured to identify a VSWR for a voltage provided by a power amplifier to the antenna; and
a power control module configured to adjust the power amplifier in response to the VSWR indicating a human body presence in proximity to the antenna.

15. The device of claim 14, wherein the VSWR module identifies the VSWR by:
detecting a reflected signal on a signal path between the power amplifier and the antenna; and
identifying the VSWR based on the reflected signal.

16. The device of claim 15, wherein the VSWR module identifies the VSWR by:
identifying a reflection coefficient based on the reflected signal and a signal transmitted to the antenna along the signal path; and
identifying the VSWR based on the reflection coefficient.

17. The device of claim 16, further comprising a directional coupler, and wherein the VSWR detector detects the reflected signal at a directional coupler in the signal path.

18. The device of claim 14, wherein the power control module is to adjust the power amplifier by:
reducing a power output of the power amplifier in response to the VSWR exceeding a threshold.

19. The device of claim 18, wherein the threshold is a programmable value.

20. The device of claim 14, wherein the power control module is to adjust the power amplifier by:
reducing a power output of the power amplifier by an adjustment amount, the adjustment amount based on the magnitude of RF reflections from the antenna.
